(19) United States
(12) Patent Application Publication
(10) Pub. No.: US 2014/0275960 A1
(43) Pub. Date: Sep. 18, 2014

(54) FUNCTIONAL MAGNETIC RESONANCE IMAGING BIOMARKER OF NEURAL ABNORMALITY

(71) Applicant: David R. Hubbard, Poway, CA (US)

(72) Inventor: David R. Hubbard, Poway, CA (US)

(21) Appl. No.: 14/210,120

(22) Filed: Mar. 13, 2014

Related U.S. Application Data
(60) Provisional application No. 61/780,030, filed on Mar. 13, 2013.
(60) Provisional application No. 61/909,631, filed on Nov. 27, 2013.

(51) Int. Cl. G01R 33/48

(52) U.S. Cl. CPC G01R 33/4806
USPC 600/410

(57) ABSTRACT

Systems and methods for application of fMRI as a biomarker of neural abnormalities are presented. A subject's activations of brain regions that occur while performing cognitive tasks in an fMRI scanning apparatus are measured. The resulting measurements are compared to the activations of brain regions that occur during each cognitive task for a control group. The comparison to the performance and brain activations of normal subjects determine the presence of cortical compensatory mechanisms that indicate neural abnormalities in the subject.

### RELATED APPLICATION

The present application claims priority to U.S. provisional patent appl. No. 61/780,030 filed 13 Mar. 2013 and also claims priority to U.S. provisional patent appl. No. 61/909,631 filed 27 Nov. 2013, each of which is incorporated herein by reference in its entirety.

### BACKGROUND

1. Field of the Invention

The present invention is generally related to functional magnetic resonance imaging (“fMRI”) and is more specifically related to using fMRI as a biomarker of neural abnormality.

2. Related Art

Recent research has raised concerns regarding the prevalence of mild traumatic brain injuries (“mTBI”) and the potential for associated long-term neurological damage as a consequence of repetitive concussive and sub-concussive injuries. The Center for Disease Control and Prevention estimates that up to 3.8 million sports related concussions occur annually in the United States alone. A vast number of additional non-sports related concussions also occur each year.

While the long-term consequences of repeated mTBI remains unclear, recent investigations indicate that at least one population group (National Football League (“NFL”) alumni) have a heightened risk of developing a host of debilitating disorders. For example, a report commissioned by the NFL showed that retired players between the ages of 30-49 were 20 times more likely, at a rate of 1.9%, to receive a diagnosis of dementia, Alzheimer's disease (“AD”) or other memory-related impairments. Over the age of 50, the proportion diagnosed with one of the above impairments rose to 6.1%, compared with only 1.2% in controls. Overall, neurodegenerative mortality of NFL alumni is 3 times greater than that of the general population, with AD and amyotrophic lateral sclerosis (“ALS”) estimated at 4 times as high. Finally, NFL alumni may also be at increased risk of developing chronic traumatic encephalopathy (“CTE”), a progressive tauopathy that is characterized by behavioural changes, memory impairments and Parkinsonism. One recent publication reported that under post-mortem analyses 89% of a non-random sample of NFL alumni showed evidence of CTE.

Despite the critical importance of these revelations regarding the effects of mTBI, the medical industry has yet to establish a reliable solution for detecting and tracking the long-term consequences of repetitive mTBI in living subjects. For example, one recent study reported that NFL alumni were impaired on global measures of cognitive function while an earlier investigation failed to find any such impairment. In other examples, discrepancies between real-life outcomes and performance on conventional neuropsychological tests of executive function are common for individuals who suffer mild to moderate traumatic brain injuries. Consequently, the long-term impact of repeated mTBI on brain function remains to be determined.

Additionally, cognitive impairments due to disease or injury are often not objectively detectable by conventional standard tests, such as a clinical neurological exam or anatomical imaging scanning. Standard neuropsychological tests, whether paper-and-pencil or computerized, are typically susceptible to poor effort or malingering. Accordingly, what is needed is a system and method that overcomes the significant problems described above.

### SUMMARY

When the brain is active, it requires an increase in blood flow to the brain cells in the active region. The increase in blood flow typically occurs after a brief delay (e.g., 1-5 seconds) and usually peaks at around 4-5 seconds. After the peak, the increased blood flow washes out and typically exhibits a negative trough before returning to a normal baseline level. This process of increased blood flow and corresponding washout is referred to as a hemodynamic response (“HDR”).

When the increased blood flow is delivered to the active region of the brain, the brain cells use the oxygen and glucose in the blood. Consequently, the deoxygenated blood remaining in the veins is paramagnetic and can be successfully imaged using magnetic resonance imaging. Imaging based on the magnetic contrast of deoxygenated blood is referred to as blood-oxygen-level dependence (“BOLD”).

Functional magnetic resonance imaging (“fMRI”) is used to capture complete scans of the brain during the HDR process, which typically takes about 15-60 seconds per stimulus event. The result of fMRI is a series of scans of the subject over time that show what region of the brain was active during the HDR. A single scan includes a full set of slices that cover the brain of the subject. Each slice is a separate image and collectively the slices comprise a three dimensional image of the brain of the subject. Typically, an image is taken every 1-4 seconds. In this fashion, fMRI is used to identify the region of the brain that is active for a particular cognitive task and any number of cognitive tasks can be presented to the subject (e.g., in the range of 5-60 cognitive tasks). fMRI allows for strong functional-anatomical identification and fMRI scans have been used to locate important brain regions, such as language regions. fMRI scans have also been used in lie detection, because the attempt to deceive causes intense activity in several distinct brain areas. Data resulting from fMRI has been found to be robust and reproducible, and fMRI has become a helpful tool of cognitive neuroscience researchers.

Differences in the HDR between subjects, performing neuropsychological testing tasks during scanning, can be used to diagnose, substantiate, measure, and otherwise quantify cognitive impairment of one or more of the subjects. HDR and/or BOLD can also be used to identify and track improvements in cognition. It should be understood that fMRI is a technically challenging procedure, and analysis and interpretation of fMRI data is complicated. As a result, fMRI results are at risk of overinterpretation or misuse by those without adequate training. This is a key issue as fMRI becomes a more widely used clinical tool to assess the functional impact of structural abnormalities from trauma or other lesions. A tool such as fMRI requires expertise and knowledge in an array of areas, including neuroanatomy, the organization of functional brain systems, brain-behavior relationships, statistical approaches for detecting and localizing brain activation, and an understanding of magnetic resonance physics and image acquisition and reconstruction artifacts. Currently, fMRI is primarily a research tool that is employed by basic and clinical neuroscientists in fields such as neurosurgery, neurology, psychiatry, and rehabilitation. Activation protocols must be reliable, sensitive to the function under investigation, and specific to the clinical use.

Other features and advantages of the present invention will become more readily apparent to those of ordinary skill in the art after reviewing the following detailed description and accompanying drawings.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 illustrates an example spatial planning cognitive task, according to an embodiment;

FIG. 2 illustrates an example spatial planning cognitive task, according to an embodiment;

FIGS. 3A-3D illustrate an example paired associates learning cognitive task, according to an embodiment;

FIGS. 4A-4D illustrate an example stop signal cognitive task, according to an embodiment;

FIG. 5 illustrates an example Stroop squared cognitive task, according to an embodiment;

FIG. 6 illustrates an active memory cognitive task, according to an embodiment;

FIG. 7 illustrates an example process for measuring cognitive impairment according to an embodiment;

FIGS. 8A-F is an example spatial planning task according to an embodiment;

FIGS. 9A-B is an example non-parametric correlation and functional connectivity analysis according to an embodiment;

FIG. 10 is an example Granger Causality analysis of affective connectivity according to an embodiment; and

FIG. 11 is a block diagram illustrating an example computer system that may be used in connection with various embodiments described herein.

### DETAILED DESCRIPTION

After reading this description it will become apparent to one skilled in the art how to implement the invention in various alternative embodiments and alternative applications. However, although various embodiments of the present invention will be described herein, it is understood that these embodiments are presented by way of example only, and not limitation. As such, this detailed description of various alternative embodiments should not be construed to limit the scope or breadth of the present invention as set forth in the appended claims.

Certain embodiments as disclosed herein provide for systems and methods to diagnose cognitive impairments. For example, one method as disclosed herein provides for converting fMRI and/or BOLD data obtained from a subject in response to one or more cognitive tasks into HDR data and then analyzing the HDR data by comparing it to HDR data of a control group performing the same one or more cognitive tasks to determine a cognitive impairment. Cognitive impairments can include, but are not limited to, motor dysfunction, mood disorders, memory and attention deficits and disorders, information processing speed, perception and the like.

The Cambridge Neuropsychological Test Automated Battery (“CANTAB”) is based on research used to identify the neural substrate of learning and memory in non-human primates. CANTAB is now used extensively in the assessment of various forms of cognitive impairment, including dementia, and has been validated on patients with neurosurgical lesions. The tests employed include, but are not limited to, pattern and spatial recognition, simultaneous and delayed matching to samples, learning of visual-spatial paired associates, matching to samples, reaction time, and spatial working memory. Key components of CANTAB can be adapted for use in fMRI, and a database of normals (or controls) can be collected. Subjects' performances on these adapted tests can be measured using fMRI, and compared to the database of normals/controls to identify, diagnose, verify, measure, and/or quantify cognitive impairments.

With reference to FIGS. 1 and 2, a spatial planning cognitive task, popularly known as the Tower-of-London, is demonstrated. In an embodiment, two racks 22, 24 are presented on a display 20 to a subject undergoing fMRI. The racks 22, 24 may be images displayed on a device, such as a television, projection screen, computer monitor, or device capable of displaying images. Each rack comprises a number of colored balls 30, 32, 34 or other objects. The subject may be instructed to “plan,” for example, by displaying an instruction or instructions (e.g., the word “plan”) on the display device 20. Additionally or alternatively, the subject may be instructed to “subtract,” for example, in the same or similar manner as the “plan” instruction.

According to an embodiment, if the subject is instructed to “plan,” the subject must work out how many moves it would take to move the balls in one of the two racks (e.g., the rack 22 at the top of the display) into the same positions as the balls in the other rack (e.g., the rack 24 at the bottom of the display). In an embodiment of the task illustrated in FIG. 1, the balls can only be moved in and out of the holes 26 at the tops of the tubes 28. Thus, if there is a first ball on top of a second ball, and the subject wishes to move the second ball, then the subject must first move the first ball into a different tube. The subject may be prompted to indicate the number of moves required to complete the objective (e.g., matching the positions of the balls in the top rack to the positions of the balls in the bottom rack), for example, using a keyboard, touch screen, mouse, button box, eye tracker, or other input device. In the illustrated embodiment, the subject is given the options of 1 move, 2 moves, 3 moves, and 4 moves, which are displayed at the bottom of the display. The subject can choose an answer 30 by entering an option selection using the input device (e.g., by pressing a button on a button box corresponding to the position in which the option 30 is displayed). It should be understood that other configurations of the user interface 20 and any of the user interfaces described herein are possible, and that the disclosed embodiments do not depend upon any particular configuration.

FIG. 2 illustrates an embodiment where the subject is instead instructed to “subtract,” the subject should subtract the number of balls held in one specified rack (e.g., the bottom rack 24) from the number of balls held in the other specified rack (e.g., the top rack 22). As with the “plan” task, the subject may select an answer 30 from a number of options 30 displayed on the display device 20 using an input device (not shown).

With reference to FIGS. 3A-3D, a paired associates learning cognitive task, popularly known as the “Go-NoGo” test, is demonstrated. In the illustrated embodiment, a set of boxes 32 (e.g., six boxes) are displayed on the screen 20. The boxes 32 open one at a time to reveal their contents, and then close to hide their contents again. For instance, some of the boxes may contain colored patterns 100, 110, 120. Once all of the boxes 32 have displayed their contents 100, 110, 120, two probe patterns (A,B) may appear side-by-side over one of the boxes as shown in FIG. 3B. The objective is for the subject to remember which boxes contain which colored patterns 100, 110, 120, and to select the correct pattern 100, 110, 120 from the two displayed probe patterns (A,B) which matches the contents of the box. The subject may indicate his or her selection by pressing a button (e.g., a left or right button) on a button pad 30. After the subject has indicated his or her selection, probe patterns (C,D) may be displayed over a different one of the boxes, as shown in FIG. 3C and the user may again make a selection. This process may continue for each of the boxes, e.g., FIG. 3D and so on. Once a subject has finished making a selection of probe patterns for each box, a new trial may begin with another set of boxes.

With reference to FIGS. 4A-4D, a stop signal cognitive task is demonstrated. In the illustrated embodiment, the subject is instructed to monitor a sequence of arrows 50,52,54,56 displayed on the display device 20. For instance, the subject may be instructed to perform the task during three ten minute fMRI scans. In an embodiment, the majority of the arrows 50,52,54,56 point either to the left (FIG. 4A) or the right (FIG. 4B). However, sometimes an arrow pointing down (FIG. 4C) or an arrow pointing up (FIG. 4D) may be displayed shortly after a left or right arrow is displayed. The subject may be instructed to respond with a first finger press on one of a set of buttons 40 corresponding to a displayed option whenever a left arrow is displayed and similarly a second finger press whenever a right arrow is displayed. However, if an up (or down) arrow is displayed, the subject should attempt to cancel the response by not pressing a button. The subject may not always be successful in canceling the response, but the objective is for the subject to attempt his or her best to cancel the response while still responding promptly to the left and right arrows.

With reference to FIG. 5, a Stroop squared cognitive task is demonstrated. In the illustrated embodiment, the objective is for the subject to remap meaning between different visual features. For instance, three words 30,32,34 may appear on the display device, e.g., one at the top and two at the bottom. In the illustrated embodiment, the words read either “red” or “green” and may be presented in the color red or green, regardless of the word. For example, the top or bottom word “red” may be the color red or the color green and the top word “red” may or may not match the color of the bottom word “red.” Similarly, the word “green” may be the color red or the color green. The subject should indicate (e.g., with an input device, such as a button pad 40) which of the two words at the bottom of the display describes the color in which the word at the top of the display is presented. For instance, if the word at the top of the display is written in the color green, the correct response would be to press the button on the right using the input device, since the word at the bottom on the right reads “green.”

With reference to FIG. 6, an active memory cognitive task is demonstrated. In an embodiment, abstract images (e.g., the image 500 shown in FIG. 6) appear on the display 20, one after another. The objective is for the subject to commit the abstract images to memory. The subject is then tested on his or her ability to remember the displayed images once the subject has left the fMRI scanner.

During one or more of the example tests mentioned above, or any number of other neuropsychological tasks, MRI scans of control subjects and test subjects can be acquired. By tracking the changes in cerebral blood flow as a subject performs the neuropsychological task or tasks the fMRI shows which brain regions become active when the subject moves, thinks, and/or feels. This functional data regarding cerebral blood flow in the subject is stored in a computer readable medium so it can later be compared to stored functional data from a group of control (normal) subjects and the comparison facilitates the identification of neural abnormalities in the subject. The ability to reveal function, and not merely structure, distinguishes fMRI from standard MRI methods, and can highlight the neural substrates of decisions, emotions, and even deceptions. Comparison of the stored results from tracking the changes in cerebral blood flow during performance of one or more neuropsychological tasks to the stored results of a control group of normal brain region function facilitates the identification of neural abnormalities in the subject.

FIG. 7 is a flow diagram illustrating an example fMRI process to measure cognitive impairment according to an embodiment of the present invention. In a broad sense, the illustrated embodiment of the present invention analyzes fMRI BOLD data and generates HDR data representing one or more cognitive tasks performed by a subject and compares that HDR data to normative HDR data representing the same one or more cognitive tasks performed by a control group to identify cognitive impairment. For example, a plurality of neuropsychological tasks are performed by a subject and HDR data is measured and stored for each of the plurality of tasks and the HDR data for each task is compared to stored HDR data from a control population (e.g., normalized individual or aggregate HDR data) to identify cognitive impairment/neural abnormality.

Initially, in step 100 of the illustrated embodiment, a subject (e.g., patient or control subject) is placed in an MR scanner having means to deliver aural and visual information to the subject. For example, the subject may be wearing headphones and positioned to observe a display monitor. In this way, the subject can be aurally and visually engaged during scanning. The subject is also holding at least one response box so the subject can interact with aural and visual stimulation. In one embodiment, only visual stimulation is used.

Next, in step 150 a standard structure T1-weighted MRI scan of the brain is taken to establish a baseline for the individual subject. In alternative embodiments, the structural MR scan may be performed before or after the functional MR scan.

Then in step 200 visual, auditory and/or cognitive tasks are presented to the subject through the headphones and/or the display monitor. For example, the spatial planning, paired associated learning, stop signal, Stroop squared, and/or active memory tasks are presented to the subject. Responses from the subject are received via an input device (e.g., one or more response boxes held in the subject's hand(s)). For example, the subject holds the response box in one hand and presses the appropriate key with the other hand.

Next in step 250 a T2-weighted scan of the brain is performed to capture images at approximately two second intervals. The scan images reflect the HDR in multiple brain regions and the resulting images include voxels (volumes of brain tissue, typically in the 1-9 mm cubed range). In step 300, the changes in the local magnetic field are measured in voxels as the subject performs the task.

In the illustrated embodiment, the analysis of the HDR is automated and incorporated into a computer that controls the scanner. Alternatively, the HDR analysis can be incorporated into a separate computer that has access to the fMRI BOLD data so that the HDR data can be generated and graphed in step 350 and then analyzed and compared to control group HDR data in step 400 to identify a cognitive impairment.

As will be understood by those skilled in the art, structural and functional MR scanning is performed in the typical manner. The resulting images can be stored in accordance with the digital imaging and communications in medicine (“DICOM”) standard and can also be exported from the scanner to a computer for the analysis. As previously described, the analysis may also be performed by the MR scanner device. As will be understood, open-source, propriety or ad hoc software may be employed to facilitate the image analysis.

In the example embodiment, a number of brain regions may be selected for analysis and the HDR calculated for each region. Patterns of HDR can be analyzed for individual regions or in combination and compared to the database in the same single or collective fashion to identify abnormal patterns.

In one embodiment, the system for presenting visual, auditory and executive tasks to a patient or research subject may be packaged into a combination of hardware and software, for example hardware and software that are incorporated into an MR apparatus. The software for analyzing the HDR data may also be incorporated into an MRI scanner device or it may be resident on a separate computer device that has access to the fMRI BOLD data that is generated by the MR scanner.

### Example Operating Environment

In one embodiment, the subject is placed in an MRI scanning apparatus configured with a patient comfort system including a visual interface (e.g., display screen, goggles, etc.). The subject is provided with an input device (e.g., a button box) that is communicatively coupled with a cognitive task module (e.g., wirelessly or via a fiber optic cable). The cognitive task module causes information related to the cognitive task to be presented on the visual interface and the subject responds to the information presented on the visual interface using the input device to accomplish the cognitive task. The MRI scanning apparatus images the subject at appropriate times in accordance with the performance of the cognitive task and the resulting data is provided to a cognitive impairment module for storage in a computer readable medium and simultaneous or subsequent analysis and comparison to control data to identify neural abnormalities. In this embodiment, the cognitive task module and the cognitive impairment module may be integrated on the same processor enabled device (e.g., a laptop computer) that is located in the control room associated with the MRI scanning apparatus. The device is communicatively coupled with the MRI scanning apparatus, the visual interface and the input device.

### Example Study

A study was recently conducted in San Diego, Calif. to analyze the use of fMRI to identify neural abnormality in subjects having multiple mTBIs.

Participants: The FANTAB normative database was used for this study. Sixty healthy volunteers from the FANTAB database were recruited from the San Diego area for this study. All volunteers are right-handed college graduates, fluent in English, with normal or corrected-to-normal eyesight, normal hearing, and no history of neurological or psychiatric illnesses. These individuals were selected to cover a range of ages, between 20 and 60 years old. In the current study, an age-matched subset of twenty volunteers was compared to the NFL group (mean age controls=53 years old, NFL alumni=54 years old). Thirteen retired American professional football players participated in the neuroimaging study. They had no diagnosis of neurological or psychiatric illness. A further two retired players volunteered but could not be included in the neuroimaging study because they did not fit within the bore of the scanner. No clinically significant MRI structural abnormalities were identified in any of the participants. All participants were right handed, had normal or corrected-to-normal eyesight and normal hearing. NFL alumni were asked to report the total number of times that they had been taken out of play due to head impact, with this measure including instances in which they returned to the game and instances in which they remained out of play. Baseline measures of IQ and education achievement were not available for the NFL cohort.

Executive paradigm: The fMRI task includes the subject being presented with two arrays of colored balls held in transparent vertical tubes. During planning trials, the subject was required to work out the minimum number of moves that would be required to rearrange the balls in the array at the top of the screen so that the balls were in the same configuration as those in the array at the bottom of the screen. The subject was instructed that he could only move the balls in and out of the top of the tubes and could only move one ball at a time. Once the subject had calculated the minimum number of moves required, the subject reported his answer by pressing the corresponding button on an fMRI compatible button box that was placed beneath the right hand. The difficulty of the planning trials varied from two to four moves.

There were also control trials, in which the same arrays were displayed but with varying numbers of balls in the upper and lower panels. During the control trials, subjects simply subtracted the number of balls in the top array from the number in the bottom and indicated the resultant value using the same button box response. This condition was intended to control for visual, attentional and motor demands and was used in a subtractive analysis to identify brain regions that were particularly active during planning. Trials were pseudo-randomised according to a predefined sequence. Stimulus arrays were displayed until the subject responded, subsequent to which there was a 10 second period of rest. The task ran for a total of 10 minutes and subjects were required to accurately solve as many problems as possible within this time. Prior to entering the scanner, subjects undertook a pre-training session, which involved reading the task instructions and undertaking a short series of practice trials.

The fMRI data were modelled at the individual subject level using fixed effects analysis in SPM8. Six predictor functions were generated, corresponding to the onsets and duration of planning and counting trials convolved with the canonical hemodynamic response function separately for trials for which the answer was 2, 3 or 4. Noise due to movement was accounted for by inclusion of six nuisance variables corresponding to translations and rotations in the x, y, and z planes. The whole brain maps, depicting beta weights for the six experimental predictor functions, were collated for group level whole brain and regions of interest (“ROI”) analyses.

Neuroimaging: fMRI data were collected using the standard 2 second EPI protocol on a Siemens 3T Tim Trio scanner at the Applied fMRI Institute in San Diego, USA. The data were pre-processed and analysed in SPM8 (Statistical Parametric Mapping, Welcome Department of Imaging Neuroscience, London, UK). Prior to analysis, data were slice-timing and motion corrected, spatially normalized to the standard Montreal Neurological Institute template and spatially smoothed with an 8 mm full width at half maximum Gaussian kernel. The data were high-passed filtered (cutoff period=180 seconds) to remove low frequency drifts in the MRI signal.

In order to examine task related functional activation, fixed effects analyses were carried out at the individual-subject level using general linear modelling. Focused regions of interest (“ROI”s) analyses were carried out with the MarsBaR toolbox, which calculates the average intensity value from all voxels within a ROI. Voxel-wise group level analyses were carried out in SPM8 and unless reported otherwise used a False Discovery Rate (“FDR”) correction of P<0.05 for multiple comparisons across the whole brain volume. Ranked Times Off (“RTO”) was calculated when examining individual differences because the number of times that the NFL alumni reported having been taken out of play after head impact was positively skewed. Non-parametric functional imaging analyses used RTO as a predictor function and were conducted using the Free Surf Library randomise function with voxel-wise thresholding at p<0.01. False positives were controlled at the cluster level using family wise error (“FEW”) correction at p<0.05 within the task localiser mask, which included all regions that were more active for task relative to rest collapsed across group at p<0.001 uncorrected.

Functional connectivity was examined using psychophysiological interaction analyses in SPM8. For each subject, timecourse data were extracted from a 10 mm radius spherical ROI using the Volume of Interest function, which extracts the first eigenvector from all voxels within the ROI. The extracted timecourse was deconvolved in order to estimate underlying neural activation from the BOLD response. The estimated timecourse of neural activation was interacted with a psychological timecourse for planning vs. counting trials. The resultant psychological, physiological and psychophysiological timecourses were convolved with the hemodynamic response function to generate a predictor of BOLD activation and these predictors were entered into a general linear model in SPM8 along with six movement variables corresponding to translations and rotations in the x, y, and z planes. The beta maps for the physiological and psychophysiological predictor functions were examined at the group level using independent sample t-tests in MarsBaR.

Affectivity connectivity was examined by Granger Causality analyses with the Granger Causality Connectivity Analysis (“GCCA”) toolbox. Mean timecourses were extracted from ROIs using MarsBaR. The timecourse were detrended and demeaned in GCCA. Optimal model orders (the number of previous observations to include in the GC model) were calculated separately for each individual using Bayesian information criteria (“BIC”) and the mean order calculated across participants. Conditional G-Causality models were fitted for each individual with lagged timecourses set to the mean BIC of 3 to ensure that model order was evenly matched across all individuals. The resultant GC magnitudes for each of the six connections were extracted for cross group analysis and GC magnitudes above 2.5 SDs from the mean replaced with the next nearest non-outlier value for the same connection in the same group. Mean GC was calculated by averaging the magnitudes for all six connections. Cross-group comparisons of GC magnitudes were conducted using independent samples t-tests with variance not assumed to be equal in SPSS.

SVM classification was undertaken using the svmtrain and svmclassify functions, which are native to Matlab. Validation used a leave-one-out approach whereby one participant data set was excluded from each round of training subsequent to which the trained SVM attempted to classify the excluded data set, to which it was naïve. This process was repeated until each individual data set had been left out and classified once in order to generate an unbiased measure of classification accuracy. The SVM used all of Matlab's default parameters including the linear kernel function (dot product) and the sequential minimal optimisation method.

In FIG. 8A, the spatial planning task is a variant on the Tower of London paradigm, which is commonly used to assess executive function. Two arrays of coloured balls are presented in vertical tubes. In the planning condition, the participant must work out the minimum number of moves that is required to rearrange the balls in the top array so that they match those in the array at the bottom. Difficulty varies from 2 to 4 moves. There are also counting trials, in which different numbers of balls are placed in the two arrays and the participant must subtract the number of balls in the top from the number in the bottom array.

In FIG. 8B, in the fMRI analysis, the counting condition is used as a visual and attentional control and contrasting planning minus counting (voxel-wise FDR correction for the whole brain mass p<0.05) localises a dorsal frontoparietal network including middle frontal gyrus, frontopolar cortex, and inferior parietal cortex bilaterally.

In FIG. 8C, in the ROI analysis, there was significantly greater activation in the DLPFC in NFL alumni relative to controls, particularly at the more difficult planning levels (error bars report 90% confidence interval).

In FIG. 8D, there was also a significant interaction between planning level and group within the frontopolar cortex ROI (error bars report 90% confidence interval).

In FIG. 8E, in accordance with the ROI analysis, NFL alumni showed extensive clusters of hyperactivation within the DLPFC bilaterally (rendered at p<0.01 with 500 voxel extent threshold. Peak coordinates significant with FDR voxel-wise correction for the whole brain mass—see Table 1A).

In FIG. 8F, the interaction between Group and planning level showed extensive clusters of hyperactivation in NFL alumni relative to controls within the frontopolar cortices (rendered at p<0.01 uncorrected with a 500 voxel extent threshold. Peak activation coordinates significant with FDR voxel-wise correction for multiple comparisons across the whole brain mass—see Table 1B).

Behavioural analysis: The One Touch Spatial Planning task (spatial planning—FIG. 8A) is an fMRI-optimised variant on the Cambridge Neuropsychological Test Automated Battery (CANTAB) task of the same name, which in turn is based on the popular Tower of London paradigm. In order to assess behaviour, the total numbers of correctly solved planning problems were examined with a 2 by 3 mixed ANOVA in SPSS, in which the within-subject factor was 2, 3 or 4 move problems (Planning Complexity) and the between-subject factor was NFL alumni vs. Control (Group). There was a significant main effect of Planning Complexity (F_{2,62}=6.176 p=0.014), no significant main effect of Group (F_{1,31}=2.462 p=0.127), and a sub-threshold Group by Planning Complexity interaction (F_{2,62}=3.04 p=0.055). Comparing total number of problems solved separately for 2, 3 and 4 move problems showed a weak effect of Group for the 4 move problems, with NFL alumni solving fewer problems than controls (2 move t=0.073 p=0.471, 3 move t=1.055 p=0.150, 4 move t=2.323 p=0.014, values 1-tailed and uncorrected). There were no significant non-parametric correlations between total number of problems solved and the ranked number of times that the NFL players reported having been sent off field due to head impact (RTO—mean=6.07 SD=8.24). When comparing the total number of correctly solved problems on an individual participant level, 2 out of 13 NFL alumni were ranked at or below the bottom 10^{th} percentile relative to controls. Examining response times in a factorial analysis of the same design showed a main effect of Planning Complexity (F_{2,62}=17.690 p<0.001), with no significant main effect of group (F_{1,31}=1.742 p=0.197) and no significant interaction with Group (F_{2,62}=1.286 p=0.284). There was no significant non-parametric correlation between mean RT during planning and RTO. When comparing overall mean RT individually, 4 out of the 13 NFL alumni were ranked at or above the slowest 10^{th} percentile relative to controls.

Functional ROI analysis: In the neuroimaging analysis, contrasting activation during planning minus activation during counting, collapsed across NFL alumni and controls, localised the expected dorsal frontoparietal network including clusters within dorsolateral prefrontal cortex (“DLPFC”), parietal cortex (“PC”) and frontopolar cortex (“FPC”). (FIG. 8B). These clusters were used to form bilateral ROIs from which mean activations were extracted for further analysis. The resultant data (FIG. 8C) were analysed using three full factorial models, in which the within-subject factor was activation relative to rest for 2, 3 and 4 move problems (Planning Complexity) and the between-subject factor was NFL alumni vs. control (Group). There was a significant main effect of Group in the DLPFC (F_{1,31}=8.72 P=0.004), but not within the PC (F_{1,31}=0.68 P=0.409) or FPC (F_{1,31}=0.28 p=0.597). There was also a significant main effect of Planning Complexity within the DLPFC (F_{2,62}=7.02 p=0.009), but not within the PC (F_{2,62}=0.59 p=0.443) or FPC (F_{2,62}=1.60 p=0.207). There was a significant interaction of Group*Planning Complexity within the DLPFC (F_{2,62}=7.88 p=0.005) and FPC (FIG. 8D) (F_{2,62}=7.34 P=0.007), but not within the PC (F_{2,62}=0.52 p=0.470). These results were driven by hyperactivation in NFL alumni within the DLPFC at all levels of planning complexity and within the FPC selectively at the higher levels of planning demand. On an individual participant level, 7 out of 13 NFL alumni were at or above the top 10 percentile relative to controls in terms of mean DLPFC activation during planning.

Functional whole brain analysis: Supplemental whole brain analyses were carried out using a 2 by 3 full factorial model in which the within-subject factor was Group and the between-subject factor was Planning Complexity. In close concordance with the ROI analyses, there was a main effect of group, with NFL alumni showing hyperactivation in bilateral DLPFC clusters (FIG. 8E, Table 1A).

TABLE 1
peak coordinates from analysis of the Spatial Planning Task

| | | | |
|---|---|---|---|
| X | Y | Z | t |

A) Planning NFL > Controls

| | | | | |
|---|---|---|---|---|
| Left DLPFC | −48 | 2 | 56 | 5.27 |
| Left DLPFC | −48 | 28 | 42 | 4.94 |
| Right | | | | |
| DLPFC | 28 | 22 | 64 | 4.52 |
| Right | | | | |
| DLPFC | 32 | 26 | 58 | 4.26 |
| preSMA | −8 | 10 | 52 | 4.31 |

B) Effect of planning level NFL > controls

| | | | | |
|---|---|---|---|---|
| Left FPC | 8 | 62 | 22 | 4.97 |
| Right FPC | −12 | 60 | 14 | 4.91 |
| ACC | 4 | 46 | 24 | 3.89 |
| Left | −18 | −58 | −44 | 4.18 |
| cerebellum | | | | |
| Right | 14 | −78 | −42 | 3.87 |
| cerebellum | | | | |

C) Non-parametric effect of RTO

| | | | | |
|---|---|---|---|---|
| RDLPFC | 42 | 26 | 42 | 4.20 |
| RDLPFC | 42 | 4 | 48 | 3.78 |
| RFPC | 48 | 42 | 22 | 3.99 |
| Precuneous | 4 | −68 | 58 | 5.24 |
| RPC | 32 | −66 | 54 | 4.60 |

More focal clusters were evident within PC bilaterally. There was a significant interaction, with additional recruitment of FPC in NFL alumni during performance of the most complex planning problems (FIG. 8F Table 1B). Non-parametric analyses, using RTO as the predictor, rendered an extensive cluster of voxels within the right DLPFC and PC (FIG. 9A Table 1C). No significant negative correlations were evident at the cluster corrected threshold.

In FIG. 9A, when the ranked number of times NFL alumni had been sent off the field due to head injury (Ranked Times Off—RTO) was used to predict activation during the spatial planning task in a non-parametric permutation analysis, extensive clusters of activation were evident in the right DLPFC extending into the FPC. A more focal cluster was also evident within the PC (image rendered at p<0.01 uncorrected with FWE cluster correction within a mask that includes all regions that are active during task relative to rest—see Table 1C).

In FIG. 9B, when beta weights for the physiological predictor function were contrasted across groups, NFL alumni showed generally lowered functional connectivity between the right DLPFC seed region and the left DLPFC, the right FPC and the PC bilaterally. Yellow regions show the t-test of beta weights for the physiological predictor collapsed across participants with FWE voxel-wise correction of p<0.05 for the whole brain mass t and p values report cross-group analyses for the indicated connections.

Functional connectivity analysis: Functional connectivity within the dorsal planning network was examined using a psychophysiological interaction (PPI) model in SPM8. In a PPI model, the timecourse of activation is extracted from a ‘seed’ region (the physiological timecourse) and is interacted with a timecourse that captures different psychological conditions. Here, the physiological timecourse was extracted from a 10 mm sphere based at the peak activation foci for planning vs. counting in the right DLPFC (x=28 y=32 z=52). The psychological timecourse was defined by time engagement in planning trials as +1, time engagement in counting trials as −1, and rest periods as 0. The psychological, physiological, and PPI timecourses were used to predict activation elsewhere in the brain at the single subject level using general linear modelling. The latter two predictor-functions generate distinct measures of functional connectivity between brain regions. Specifically, the physiological function captures the general correlation in activation between brain regions once activation due to the specified psychological conditions has been accounted for. Conversely, the PPI captures psychologically specific correlation—that is, the difference in the correlations between brain regions when the specified psychological conditions vary. Mean beta weights for the psychological and PPI predictors were extracted from 10 mm spherical ROIs defined at peak activation coordinates for the contrast of planning vs. counting trials (left DLPFC x=−22 y=14 z=58; left PC x=−34 y=−78 z=38; right PC x=44 y=−70 z=34; right FPC x=28 y=50 z=4) and the resultant data analysed at the group level. Examining the beta weights for the PPI predictor functions collapsed across groups in a one-sample t-test did not reveal any significant condition dependent correlations in activation (Table 2A).

TABLE 2
functional connectivity analyses

| | | |
|---|---|---|
| Con | t | P (one tailed) |

General connectivity
A) Collapsed

| | | | |
|---|---|---|---|
| Left PC | 0.41 | 7.96 | p < 0.001 |
| Right PC | 0.53 | 6.36 | p < 0.001 |
| Left DLPFC | 0.81 | 11.95 | p < 0.001 |
| Right FPC | 0.50 | 5.88 | p < 0.001 |

B) Control > NFL alumni

| | | | |
|---|---|---|---|
| Left PC | 0.19 | 3.66 | p < 0.001 |
| Right PC | 0.17 | 2.02 | 0.052 |
| Left DLPFC | 0.24 | 3.56 | p < 0.001 |
| Right FPC | 0.34 | 4.00 | p < 0.001 |

Psychophysiological interaction
C) Collapsed

| | | | |
|---|---|---|---|
| Left PC | −0.13 | −1.93 | 0.063 |
| Right PC | −0.11 | −1.62 | 0.117 |
| Left DLPFC | 0.20 | 2.01 | 0.054 |
| Right FPC | 0.08 | 0.81 | 0.424 |

D) Control > NFL alumni

| | | | |
|---|---|---|---|
| Left PC | 0.06 | 0.85 | 0.402 |
| Right PC | 0.06 | 0.85 | 0.403 |
| Left DLPFC | 0.05 | 0.51 | 0.613 |
| Right FPC | −0.04 | −0.42 | 0.675 |

Nor were there any significant cross-group differences in the strength of the PPI (Table 2B). Examining the beta weights for the physiological predictor function collapsed across groups in a one-sample t-test revealed strong connectivity between the right DLPFC and the other dorsal planning network ROIs (Table 2C—FIG. 9B). Contrasting the data across groups revealed generally lowered functional connectivity for NFL alumni relative to controls in all ROIs (Table 2D—FIG. 9B). 12/13 NFL alumni were at or below the bottom 10% of controls in terms of mean functional connectivity between right DLPFC and other sub-regions of the dorsal planning network. There was a strong negative correlation (r=−0.61) between RTO and mean functional connectivity between right DLPFC and other dorsal planning network sub-regions.

Affective connectivity analysis: Whereas functional connectivity examines correlations between different brain regions at the same time point, affective connectivity measures the level at which activation in one region is predicted by activations that occurred at earlier time points elsewhere in the brain. In this respect, affective connectivity gives a measure of the activation flow between network sub-components. Here Granger Causality (“GC”) was used to examine whether there were differences between NFL alumni and controls in the affective connectivity of the dorsal frontoparietal network. Mean activation timecourses were extracted from 10 mm spherical ROIs defined at peak coordinates for the contrast of planning vs. counting within the right DLPFC, right FPC and right PPC (see previous section). These timecourses were pre-processed and a granger causality model fitted to each individual's data set using the Granger Causality Connectivity Analysis Toolbox (see methods). When GC measures were averaged across all connections and compared across groups (FIG. 10 & Table 3), NFL alumni showed significantly lowered mean GC relative to controls.

TABLE 3
Granger Causality - Cross Group Analyses

| | t | p (one-tailed) |
|---|---|---|
| Mean GC | 2.528 | 0.009 |
| FPC −> DLPFC | 2.268 | 0.017 |
| PC −> DLPFC | 1.907 | 0.034 |
| DLPFC −> FPC | 0.532 | 0.300 |
| PC −> FPC | 1.978 | 0.029 |
| DLPFC −> PC | 0.019 | 0.493 |
| FPC −> PC | 0.798 | 0.216 |

In FIG. 10, NFL alumni had lowered mean GC within the dorsal frontoparietal network relative to controls. This abnormal affective connectivity was characterised by a significant reduction in GC from the PC to the DLPFC, from the FPC to the DLPFC, and from the PC to the FPC. Red lines represent links with significantly reduced GC in NFL alumni relative to controls. Inset graphs display GC for NFL alumni and control groups with error bars reporting the standard error of the mean.

Comparing GC measures across groups for each connection (Table 3), revealed significantly lowered GC in NFL alumni relative to controls in connections to the DLPFC from the PC and the FPC, and in connections to the FPC from the PC. Three of the NFL alumni were within the bottom 10% relative to controls in terms mean GC. There were no significant correlation between RTO and GC.

Development of an mTBI Polymarker using Machine Learning:

A support vector machine (“SVM”) was used to generate a polymarker for classifying NFL alumni, and distance from the hyperplane was calculated to examine the relationship between classification dimensions and the number of mTBIs suffered. Data from the analyses reported in the previous sections were arranged into an input matrix that included behavioural performance measures at each level of planning demand (2, 3 and 4 move problems), activation levels for each ROI (DLPFC, PC, FPC bilaterally) at each level of planning demand, psychophysiological and physiological weights from each ROI from the PPI analysis, and the GC connectivity weights. Each row in the input matrix contained all measures from one individual and each column contained the same measure for all individuals (e.g. performance at level m4). There was also a column with the categorical (NFL vs. Control) labels. A leave-one-out validation approach was applied as follows. One participant was removed and the SVM identified the most optimal hyperplane for classifying the remaining individuals as NFL alumni or controls based on the combination of imaging and behavioural measures. The trained machine then attempted to classify the remaining individual, to whose data it was naïve. This process was repeated until each individual had been excluded and classified once. The entire process was then repeated 10,000 times, but with the categorical labels randomly permuted in order to generate a null distribution (mean accuracy=49.3% SD=+/−11.1%). When all of the behavioural and neuroimaging measures were input to the SVM together, it classified individuals with an overall accuracy of ˜84% (p<0.001, accuracy for NFL alumni=77% accuracy for controls=89%). When the SVM machine was trained using all data sets together, distance from the hyperplane correlated significantly with the RTO measure in the NFL alumni group (non-parametric correlation=0.55 p<0.05). Further exploratory analyses were conducted to gauge the accuracy of categorisation when using data from individual analyses, these being the behavioural performances (63%), the physiological PPI weights (84%), the psychophysiological PPI weights (78%), the GC weights (53%) and the ROI activation levels during planning (75%). The best discrimination accuracy was achieved when all measures except for those from the behavioural and GC analyses were input to the SVM (NFL alumni=84% controls=95%).

Despite growing concern regarding the long-term health of sports players who suffer from repetitive mTBIs, few studies have been conducted investigating the status of retired professional players at the levels of both brain and behaviour. The present study may in fact be the first joint computerized neuropsychological and functional magnetic resonance imaging study in a population sample with a history of concussion and the first attempt to examine functional connectivity within this population. In accordance with previous behavioural studies, only small differences for NFL alumni were observed relative to controls when performing a computerized test of executive function. By contrast, results from the fMRI analyses revealed far more pronounced abnormalities in functional activation within the dorsal frontoparietal network. These in-vivo findings extend previous post-mortem and epidemiological studies by demonstrating that hyperfrontalility and frontoparietal hypoconnectivity are cumulative long-term consequences of repetitive mTBI.

The current study provides converging evidence to support the view that long-term cortical compensatory mechanisms work to counter the neurological impact of repetitive mTBI. For example, the NFL alumni exhibited pronounced hyperactivation within the same DLPFC regions that were engaged by controls during planning and retrieval. This hyperactivation was evident at all levels of planning complexity and for all levels of working-memory load, including those for which there was no significant difference in performance. The profile of activation within the DLPFC was also qualitatively different between groups as it scaled significantly according to planning demands in NFL alumni but not in controls. Moreover, frontopolar regions were selectively recruited in the NFL alumni during more difficult trials whereas in controls no such activation was evident. Thus, additional cortical resources were brought on line in NFL alumni in order to cope with heavier planning demands. The observation of frontal-lobe hyperactivation is consistent with results from previous research investigating functional brain activation in college athletes during the acute phase shortly after concussion. However, the results presented here demonstrate that across the life span, hyperfrontality either persists or resurfaces.

The functional and affective connectivity analyses provide novel insights regarding the nature of the underlying abnormality. More specifically, in the PPI analysis the NFL alumni had greatly reduced functional connectivity within the dorsal frontoparietal network. The reduction in functional connectivity was not specific to certain psychological conditions as it was consistent across planning and counting trials. The GC analysis demonstrates that hypoconnectivity was not symmetrical throughout the frontoparietal network but rather, was characterised by significant reductions in affective connectivity to the DLPFC and FPC but not to the PC. Thus, it would appear that the NFL alumni suffer from a lack of dorsal frontoparietal network coherence and abnormal causal flow. This pattern of results fits particularly closely with an inefficiency model, in which long distance connectivity within the frontoparietal network is disrupted and as a consequence, frontal lobe sub-regions work harder when dealing with executive cognitive demands.

The strength of the neuroimaging results should be contrasted with the relative weakness of the behavioural differences. More specifically, a core aim of neuropsychological testing is the development of sensitive biomarkers that can be used to confirm neurological impairments. The results of the group level analyses suggest that when quantifying the long-term neurological impact of mTBIs, functional neuroimaging can provide more sensitive biomarkers than behavioural testing alone. For example, the behavioural differences that were observed in the spatial planning task were barely significant at the group level. This result is in line with the broader sports-mTBI literature, in which reports of longer-term impairments are typically modest and hard to replicate. By contrast, the functional neuroimaging results showed robust effects in terms of both hyperactivation and hypoconnectivity in NFL alumni. The hyperactivation was evident both when examining ROIs that focused on brain regions associated with task demands and when applying a stringent voxel-wise whole brain corrected threshold. It should be noted that the ROI analyses were specifically designed to match the behavioural analyses with respect to the design and therefore, the degrees of freedom of the group-level models. Thus, the greater sensitivity of the neuroimaging analyses cannot be accounted for by any increased statistical power inherent in the factorial model. Simple scaling of the fMRI signal also cannot account for the observed results, as hyperactivation differed qualitatively across groups, and was specific to certain brain regions (i.e., DLPFC not PPC) under certain conditions (e.g. FPC under heavier planning loads). Moreover, connectivity measures were lower not higher in NFL alumni. Instead, the relative weakness of the behavioural results is most likely to be a consequence of cognitive coping strategies and cortical compensatory mechanisms that work to counter the behavioural consequences of an acquired executive impairment.

NFL alumni are a particularly difficult population to recruit for research studies of this type. However, they offer a unique opportunity to examine how individual differences in number of mTBIs suffered relate to individual differences in behavioural and neural abnormalities. Thus, it is particularly noteworthy that both hyperfrontality and hypoconnectivity were related to the total number of head collisions of great enough severity to warrant being removed from play. These correlational analyses effectively rule out lifestyle variables that may differ across the two groups as potential confounds and moreover, support the view that repetitive mTBIs have a cumulative impact in the longer term.

Indeed, more broadly, individuals who suffer from TBI often show little impairment on lab-based neuropsychological tests of executive function, yet the epidemiological data suggests that the longer-term outcomes for many such individuals are particularly poor. In light of the current results, it seems likely that this inconsistency between assessments and outcomes is a consequence of similar cortical compensatory mechanisms operating in these related groups. Such compensatory mechanisms could adequately mask behavioural impairments in tests of executive function within the lab whilst failing to fully compensate in more complex real-world scenarios. In accordance with this view, it has previously been observed that the most commonly applied tests of executive function are poor predictors of real life executive impairments and therefore, lack both sensitivity and ecological validity. This view fits particularly well with the current results, because whilst none of the NFL alumni tested here had previously been diagnosed with a cognitive impairment and cross-group behavioural differences were barely significant, many of them reported that they were experiencing distressing cognitive problems in every day life. Thus while they are not classified as patients based on behavioural assessments, they should be based on the conjunction of evidence from previous post-mortem studies, the self report of real life executive problems, and the observation of pronounced functional brain abnormalities within a frontoparietal network that is affected in dysexecutive neurological and psychiatric populations. Similar fMRI results may be present in other populations that suffer from mTBI, requiring diagnosis and prognosis. Importantly, the measures of abnormal functional activation and functional connectivity provide a useful supplement to traditional lab based behavioural assessments when confirming neural abnormalities and also provide a very sensitive biomarker for initial diagnosis of neural abnormalities.

In fact, biomarkers that may be used to confirm neurological abnormalities at the individual participant level are notoriously difficult to develop but are also of great potential value. For example, a sensitive marker of frontal-lobe dysfunction might be used to confirm an acquired executive impairment when negotiating financial compensation for the long-term side effects of acquired injuries. Consequently, it is notable that the functional neuroimaging analyses were far more effective than behavioural testing when subdividing NFL alumni and controls at the individual participant level. More specifically, when the 90^{th} percentile was taken as the criterion for abnormal performance, ˜15% and ˜31% of the NFL alumni were classified as low performers on the spatial planning task using accuracy and RT as measures respectively. By contrast, ˜53% were classified as functionally abnormal based on hyperactivation within the DLPFC during planning. 92% were within the bottom 10 percentile based on the functional connectivity analysis. Furthermore, whereas DLPFC functional activation and functional connectivity were found to correlate strongly with the ranked number of times players were sent off field due to head injury, behavioural data failed to show a statistically significant relationship. Thus the brain imaging data can provide more accurate detection and assessment of the level of damage acquired. In such cases, the most convincing method for confirming that a neurological abnormality has been acquired, may be the decision of a previously trained learning machine that takes into account behavioural and imaging measures together. Once trained on a normal population, the machine is used to pass an unbiased judgement on whether an individual is most similar to a normal control group or most similar to a patient with a history of concussion in terms of their behavioural and functional activation profiles, thereby providing a polymarker. Here, the SVM was able to make this categorical decision with between 84% and 90% accuracy depending on the set of information that was input to the machine. Critically, the distance from the hyperplane that separates controls from NFL alumni, correlated significantly with the RTO measure, supporting the view that the parameters that guided this classification decision were related to mTBI. Future longitudinal studies should determine whether this polymarker can also provide an early warning sign of accumulating damage prior to the development of behavioural symptoms in an individual in order to warn them that preventative measures should be taken.

However, when individual differences in connectivity and activity were examined using both ROI and voxel-wise analyses in the control group, there was no significant relationship with task performance measures including overall accuracy and response time in ROI or voxel-wise whole brain analyses. Nor were any significant correlations observed when using education level as a predictor in the entire FANTAB normative database. Weight, head size, and brain dimensions did not correlate significantly with DLPFC activation in the NFL or control groups. Nor was brain size significantly different across the NFL and control groups. The FANTAB normative database also includes both males and females. However, there were no statistically significant differences between functional activation within any of the ROIs examined here or with whole brain analysis when contrasting males and females within the normative cohort. Furthermore, contrasting NFL alumni with age matched male controls only (N=13) still generated a robust cross-group effect in terms of DLPFC hyperactivation and hypoconnectivity. In fact, of the various correlations examined, only age, which was matched across groups, showed significant effects in controls, with a modest correlation in terms of DLPFC-PC connectivity (left t=1.77 p<0.05, right t=1.72 p=0.05). These modest effects of age, were dwarfed by the scale of the NFL-control effects and more importantly, stand in stark contrast to the reliability of the correlations with the RTO measure. When the individual differences and cross group analyses are considered together, the results accord particularly closely with the hypothesis that exposure to repetitive mTBI during the course of the professional NFL career leads to abnormal frontal lobe function.

In summary, the results of the example study demonstrate that cortical compensatory mechanisms work to counteract disrupted dorsal executive network connectivity in purportedly healthy patients who have suffered repetitive mTBI. These changes are important in light of the inconsistencies in the neuropsychological literature and the increased incidence of neurological disease and neurodegenerative mortality among sufferers of mild to moderate TBI. The relationship between history of mTBI, abnormal frontoparietal function, and long-term outcomes clearly merits further investigation. This method has the potential to derive the neural fingerprint of mTBI in order to provide an early warning sign when repeated injuries are accumulating towards long-term cognitive impairment.

FIG. 11 is a block diagram illustrating an example wired or wireless system 550 that may be used in connection with various embodiments described herein. For example the system 550 may be used as or in conjunction with an fMRI system or an fMRI analysis station or an MRI apparatus. The system 550 can be part of a conventional personal computer, computer server, personal digital assistant, smart phone, tablet computer, MRI apparatus or any other processor enabled device that is capable of wired or wireless data communication. Other computer systems and/or architectures may be also used, as will be clear to those skilled in the art.

The system 550 preferably includes one or more processors, such as processor 560. Additional processors may be provided, such as an auxiliary processor to manage input/output, an auxiliary processor to perform floating point mathematical operations, a special-purpose microprocessor having an architecture suitable for fast execution of signal processing algorithms (e.g., digital signal processor), a slave processor subordinate to the main processing system (e.g., back-end processor), an additional microprocessor or controller for dual or multiple processor systems, or a coprocessor. Such auxiliary processors may be discrete processors or may be integrated with the processor 560.

The processor 560 is preferably connected to a communication bus 555. The communication bus 555 may include a data channel for facilitating information transfer between storage and other peripheral components of the system 550. The communication bus 555 further may provide a set of signals used for communication with the processor 560, including a data bus, address bus, and control bus (not shown). The communication bus 555 may comprise any standard or non-standard bus architecture such as, for example, bus architectures compliant with industry standard architecture (“ISA”), extended industry standard architecture (“EISA”), Micro Channel Architecture (“MCA”), peripheral component interconnect (“PCI”) local bus, or standards promulgated by the Institute of Electrical and Electronics Engineers (“IEEE”) including IEEE 488 general-purpose interface bus (“GPIB”), IEEE 696/S-100, and the like.

System 550 preferably includes a main memory 565 and may also include a secondary memory 570. The main memory 565 provides storage of instructions and data for programs executing on the processor 560. The main memory 565 is typically semiconductor-based memory such as dynamic random access memory (“DRAM”) and/or static random access memory (“SRAM”). Other semiconductor-based memory types include, for example, synchronous dynamic random access memory (“SDRAM”), Rambus dynamic random access memory (“RDRAM”), ferroelectric random access memory (“FRAM”), and the like, including read only memory (“ROM”).

The secondary memory 570 may optionally include a internal memory 575 and/or a removable medium 580, for example a floppy disk drive, a magnetic tape drive, a compact disc (“CD”) drive, a digital versatile disc (“DVD”) drive, etc. The removable medium 580 is read from and/or written to in a well-known manner. Removable storage medium 580 may be, for example, a floppy disk, magnetic tape, CD, DVD, SD card, etc.

The removable storage medium 580 is a non-transitory computer readable medium having stored thereon computer executable code (i.e., software) and/or data. The computer software or data stored on the removable storage medium 580 is read into the system 550 for execution by the processor 560.

In alternative embodiments, secondary memory 570 may include other similar means for allowing computer programs or other data or instructions to be loaded into the system 550. Such means may include, for example, an external storage medium 595 and an interface 570. Examples of external storage medium 595 may include an external hard disk drive or an external optical drive, or and external magneto-optical drive.

Other examples of secondary memory 570 may include semiconductor-based memory such as programmable read-only memory (“PROM”), erasable programmable read-only memory (“EPROM”), electrically erasable read-only memory (“EEPROM”), or flash memory (block oriented memory similar to EEPROM). Also included are any other removable storage media 580 and communication interface 590, which allow software and data to be transferred from an external medium 595 to the system 550.

System 550 may also include an input/output (“I/O”) interface 585. The I/O interface 585 facilitates input from and output to external devices. For example the I/O interface 585 may receive input from a keyboard or mouse and may provide output to a display. The I/O interface 585 is capable of facilitating input from and output to various alternative types of human interface and machine interface devices alike.

System 550 may also include a communication interface 590. The communication interface 590 allows software and data to be transferred between system 550 and external devices (e.g. printers), networks, or information sources. For example, computer software or executable code may be transferred to system 550 from a network server via communication interface 590. Examples of communication interface 590 include a modem, a network interface card (“NIC”), a wireless data card, a communications port, a PCMCIA slot and card, an infrared interface, and an IEEE 1394 fire-wire, just to name a few.

Communication interface 590 preferably implements industry promulgated protocol standards, such as Ethernet IEEE 802 standards, Fiber Channel, digital subscriber line (“DSL”), asynchronous digital subscriber line (“ADSL”), frame relay, asynchronous transfer mode (“ATM”), integrated digital services network (“ISDN”), personal communications services (“PCS”), transmission control protocol/Internet protocol (“TCP/IP”), serial line Internet protocol/point to point protocol (“SLIP/PPP”), and so on, but may also implement customized or non-standard interface protocols as well.

Software and data transferred via communication interface 590 are generally in the form of electrical communication signals 605. These signals 605 are preferably provided to communication interface 590 via a communication channel 600. In one embodiment, the communication channel 600 may be a wired or wireless network, or any variety of other communication links. Communication channel 600 carries signals 605 and can be implemented using a variety of wired or wireless communication means including wire or cable, fiber optics, conventional phone line, cellular phone link, wireless data communication link, radio frequency (“RF”) link, or infrared link, just to name a few.

Computer executable code (i.e., computer programs or software) is stored in the main memory 565 and/or the secondary memory 570. Computer programs can also be received via communication interface 590 and stored in the main memory 565 and/or the secondary memory 570. Such computer programs, when executed, enable the system 550 to perform the various functions of the present invention as previously described.

In this description, the term “computer readable medium” is used to refer to any non-transitory computer readable storage media used to provide computer executable code (e.g., software and computer programs) to the system 550. Examples of these media include main memory 565, secondary memory 570 (including internal memory 575, removable medium 580, and external storage medium 595), and any peripheral device communicatively coupled with communication interface 590 (including a network information server or other network device). These non-transitory computer readable mediums are means for providing executable code, programming instructions, and software to the system 550.

In an embodiment that is implemented using software, the software may be stored on a computer readable medium and loaded into the system 550 by way of removable medium 580, I/O interface 585, or communication interface 590. In such an embodiment, the software is loaded into the system 550 in the form of electrical communication signals 605. The software, when executed by the processor 560, preferably causes the processor 560 to perform the inventive features and functions previously described herein.

The system 550 also includes optional wireless communication components that facilitate wireless communication over a voice and over a data network. The wireless communication components comprise an antenna system 610, a radio system 615 and a baseband system 620. In the system 550, radio frequency (“RF”) signals are transmitted and received over the air by the antenna system 610 under the management of the radio system 615.

In one embodiment, the antenna system 610 may comprise one or more antennae and one or more multiplexors (not shown) that perform a switching function to provide the antenna system 610 with transmit and receive signal paths. In the receive path, received RF signals can be coupled from a multiplexor to a low noise amplifier (not shown) that amplifies the received RF signal and sends the amplified signal to the radio system 615.

In alternative embodiments, the radio system 615 may comprise one or more radios that are configured to communicate over various frequencies. In one embodiment, the radio system 615 may combine a demodulator (not shown) and modulator (not shown) in one integrated circuit (“IC”). The demodulator and modulator can also be separate components. In the incoming path, the demodulator strips away the RF carrier signal leaving a baseband receive audio signal, which is sent from the radio system 615 to the baseband system 620.

If the received signal contains audio information, then baseband system 620 decodes the signal and converts it to an analog signal. Then the signal is amplified and sent to a speaker. The baseband system 620 also receives analog audio signals from a microphone. These analog audio signals are converted to digital signals and encoded by the baseband system 620. The baseband system 620 also codes the digital signals for transmission and generates a baseband transmit audio signal that is routed to the modulator portion of the radio system 615. The modulator mixes the baseband transmit audio signal with an RF carrier signal generating an RF transmit signal that is routed to the antenna system and may pass through a power amplifier (not shown). The power amplifier amplifies the RF transmit signal and routes it to the antenna system 610 where the signal is switched to the antenna port for transmission.

The baseband system 620 is also communicatively coupled with the processor 560. The central processing unit 560 has access to data storage areas 565 and 570. The central processing unit 560 is preferably configured to execute instructions (i.e., computer programs or software) that can be stored in the memory 565 or the secondary memory 570. Computer programs can also be received from the baseband processor 610 and stored in the data storage area 565 or in secondary memory 570, or executed upon receipt. Such computer programs, when executed, enable the system 550 to perform the various functions of the present invention as previously described. For example, data storage areas 565 may include various software modules (not shown) that are executable by processor 560.

Various embodiments may also be implemented primarily in hardware using, for example, components such as application specific integrated circuits (“ASICs”), or field programmable gate arrays (“FPGAs”). Implementation of a hardware state machine capable of performing the functions described herein will also be apparent to those skilled in the relevant art. Various embodiments may also be implemented using a combination of both hardware and software.

In an embodiment where the system 550 is incorporated into an MRI apparatus, the MRI scanner's resolution—the smallest volume detectable, called a voxel—is about the size of a grain of rice (e.g., 1 mm×1 mm×1 mm; or in some embodiments e.g., 1 mm×1 mm×3 mm). There are over 150,000 voxels in the brain. In a typical experiment a subject lies in the center of the MRI apparatus' magnet for a period of time (e.g., 30 seconds) to acquire a baseline. The subject then performs the required task (e.g., for another 30 seconds). This baseline-then-task pattern can be repeated several times. For each voxel, the magnetic signal during the task is compared to the signal during the baseline. The brain regions with stronger signals during the task are presumed to be processing the information that underlies the performance of the task. It is important to note that a voxel is not necessarily the same as a neuron; in fact, each voxel typically measures the activity of tens of thousands of neurons.

In an embodiment, structural scans at the resolution of 1×1×1 mm voxels may be acquired using MP-RAGE protocol (TR/TE/TI=1900/2.26/900 ms, flip angle=9 deg). Functional T2*-weighted images may be acquired using gradient echo EPI sequence with parameters TR/TE=2000/25 ms, flip angle=90 degrees, 36 slices of thickness=3 mm, in-plane resolution: 3.75×3.75 mm2, spacing between slices=4 mm. The number of repetitions was 463 resulting in scan duration of 15.37 minutes.

In one embodiment, as part of the example test MRI, image preprocessing and processing steps can be performed with a custom-developed analysis toolbox for Matlab (MathWorks, Natic, Mass.) with integrated calls to a subset of functions from the AFNI (Cox, 1996), FSL (Smith et al., 2004) and mrVista (mrVista, 2011) software packages. Other software packages and analysis tools may also be used as will be understood by those skilled in the art. Structural scans can be processed by computationally removing skull and aligning to the Talairach-Tourneaux space (TT-space). Functional scans can be smoothed with a five mm smoothing kernel, resampled at four mm resolution, head motion can be corrected by aligning volumes at each time point to a reference volume and the resulting volumes may be stripped of skull, aligned to structural scans and mapped to the TT-space. A reference function, created by convolving task occurrence times with a standard gamma distribution function, may be used for calculation of first-level individual t-maps by means of a generalized least squares fitting procedure as implemented in 3dREMLfit. Head motion parameters may be projected out from fMRI time series at this step. At the second step, group statistical maps may be calculated using a mixed-effects procedure implemented in 3dMEMA. Mixed-effects t-maps can be generated for each experimental group (controls, test) as well as for group differences (control vs. test). Group t-maps for the control group can be thresholded at p<0.05 (|t|>2.1) and multiple comparison-corrected significantly active voxel clusters may then be determined using permutation analysis (p<0.01).

For evaluation of the extent of active regions in terms of the number of active voxels and time course of hemodynamic responses masks can be created for regions of interest (“ROI”) in the following way: active voxel clusters determined in pooled group analysis of control and test subjects, as described above, can be intersected with anatomy-based regions derived from the Talairach-Tourneaux atlas, thus resulting in anatomically constrained cortical and subcortical ROI masks for both task-positive areas (positive response magnitudes) and task-negative areas.

This procedure assures minimum circularity in fMRI data analysis. For quantification of task-related effects in different ROIs, the number of significantly activated (p<0.01, corrected) or suppressed (p<0.05, corrected) voxels may be counted within each ROI of each subject and group mean and standard error can be calculated.

Next, for estimation of hemodynamic response function shapes, these ROIs can be used to constrain significantly active voxels for extraction of time series of individual scans. The specificity of BOLD response increases when weakly responding or low signal to noise ratio (“SNR”) voxels can be eliminated from analysis by increasing the t-map threshold. The voxels with maximum response magnitude contain large draining veins. For task-positive and task-negative ROIs different t-values can be used that yield comparable BOLD response specificity. Hence, for task-positive voxels P6 can be used and for the task-negative voxels t<−4 can be used. These values may result in consistent detection of activation in both task-positive and task-negative areas of test patients. The time series data can be smoothed in the temporal domain (e.g., Gaussian kernel of two second standard deviation) and averaged both voxel-wise and block-wise and the peak value can be normalized to one (1) for each subject before calculating group averaged HDRs and standard errors of the mean.

Those of skill in the art will appreciate that the various illustrative logical blocks, modules, circuits, and method steps described in connection with the above described figures and the embodiments disclosed herein can often be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled persons can implement the described functionality in varying ways for each particular application, but such implementation decisions should not be interpreted as causing a departure from the scope of the invention. In addition, the grouping of functions within a module, block, circuit or step is for ease of description. Specific functions or steps can be moved from one module, block or circuit to another without departing from the invention.

Moreover, the various illustrative logical blocks, modules, and methods described in connection with the embodiments disclosed herein can be implemented or performed with a general purpose processor, a digital signal processor (“DSP”), an ASIC, FPGA or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

Additionally, the steps of a method or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium including a network storage medium. An exemplary storage medium can be coupled to the processor such the processor can read information from, and write information to, the storage medium. In the alternative, the storage medium can be integral to the processor. The processor and the storage medium can also reside in an ASIC.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly not limited.

1. A method for identifying a neural abnormality in a subject, comprising:
acquiring magnetic resonance image (MRI) data of a subject using an MRI apparatus;
during acquisition of the MRI data,
presenting a cognitive task to the subject, and
receiving a response from the subject;
analyzing the MRI data to determine a measure of activation in one or more areas of a brain of the subject in response to the cognitive task;
comparing the measure of activation in one or more areas of the brain of the subject to a measure of activation in a corresponding one or more areas of brains of a control population;
determining the presence of one or more cortical compensatory mechanisms in the subject based on said comparison; and
identifying a neural abnormality in the subject in accordance with said determined presence of the one or more cortical compensatory mechanisms.

2. The method of claim 1, wherein the neural abnormality comprises a cognitive impairment.

3. The method of claim 1, wherein the neural abnormality comprises a mild traumatic brain injury.

4. The method of claim 1, further comprising presenting a plurality of cognitive tasks to the subject and receiving a plurality of responses from the subject.

5. The method of claim 4, wherein the plurality of cognitive tasks comprises a range of 5 to 60 cognitive tasks.

6. The method of claim 1, wherein the cognitive task is presented on a visual interface.

7. The method of claim 1, wherein the cognitive task is presented via an audio interface.

8. The method of claim 1, wherein the response to the cognitive task is received via a touch input device.

9. The method of claim 1, wherein the response to the cognitive task is received via an audio input device.

10. The method of claim 1, wherein the response to the cognitive task is received via an eye tracker input device.

11. A functional magnetic resonance scanner apparatus comprising at least one processor communicatively coupled with at least one non-transitory computer-readable medium, wherein the processor is programmed to identify localized areas of brain activation in response to one or more cognitive tasks presented to a subject in the scanner in order to compare the subject's brain activations in response to the one or more cognitive tasks to a control population's brain activations in response to the same one or more cognitive tasks to identify a neural abnormality in the subject.

12. The apparatus of claim 11, wherein the neural abnormality comprises a cognitive impairment.

13. The apparatus of claim 11, wherein the neural abnormality comprises a mild traumatic brain injury.

14. The apparatus of claim 11, wherein the one or more cognitive tasks comprises a plurality of cognitive tasks.

15. The apparatus of claim 14, wherein the plurality of cognitive tasks comprises a range of 5 to 60 cognitive tasks.

16. The apparatus of claim 11, wherein the one or more cognitive tasks are presented on a visual interface.

17. The apparatus of claim 11, wherein the one or more cognitive tasks are presented via an audio interface.

18. The apparatus of claim 11, wherein one or more responses to the one or more cognitive tasks are received via a touch input device.

19. The apparatus of claim 11, wherein one or more responses to the one or more cognitive tasks are received via an audio input device.

20. The apparatus of claim 11, wherein one or more responses to the one or more cognitive tasks are received via an eye tracker input device.

21. A system for identifying a neural abnormality in a subject arranged in a magnetic resonance imaging scanning apparatus such that the subject can see a visual interface and provide input to an input device, the system comprising:
a non-transitory computer readable medium configured to store executable programmed modules;
a processor communicatively coupled with the non-transitory computer readable medium configured to execute programmed modules stored therein;
a cognitive task module stored in the non-transitory computer readable medium and configured to be executed by the processor, the cognitive task module configured to present information on the visual interface and receive input from the input device; and
a cognitive impairment module stored in the non-transitory computer readable medium and configured to be executed by the processor, the cognitive impairment module configured to receive data from the MRI scanning apparatus and the cognitive task module and analyse said received data in comparison to data representative of a control group and identify a neural abnormality based on said analysis.

22. The system of claim 21, wherein said cognitive impairment module is further configured to compare a measure of activation in one or more areas of the brain of the subject to a measure of activation in a corresponding one or more areas of brains of a control population.

23. The system of claim 22, wherein said cognitive impairment module is further configured to determine the presence of one or more cortical compensatory mechanisms in the subject based on said comparison.

24. The system of claim 23, wherein said cognitive impairment module is further configured to identify a neural abnormality in the subject in accordance with said determined presence of the one or more cortical compensatory mechanisms.
